(19) United States
(12) Patent Application Publication
(10) Pub. No.: US 2025/0239464 A1
(43) Pub. Date: Jul. 24, 2025

(54) HIGH-PRESSURE SUBSTRATE PROCESSING APPARATUS AND PROCESSING GAS LINE USED THEREFOR

(71) Applicant: HPSP Co., Ltd., Hwaseong-si (KR)

(72) Inventor: Kunyoung LIM, Suwon-si (KR)

(21) Appl. No.: 19/173,441

(22) Filed: Apr. 8, 2025

Related U.S. Application Data
(63) Continuation of application No. PCT/KR2023/017487, filed on Nov. 3, 2023.

(30) Foreign Application Priority Data
Nov. 4, 2022 (KR) 10-2022-0146555

(51) Int. Cl. H01L 21/67

(52) U.S. Cl. CPC H01L 21/67017

(57) ABSTRACT

The present invention provides a high-pressure substrate processing apparatus and a processing gas line used therefor. The high-pressure substrate processing apparatus comprises: an inner chamber having an inner housing formed to accommodate a substrate to be processed, and an inner door formed to be movable between a locked position for enclosing the inner housing and an open position for opening the inner housing; an outer chamber having an outer housing disposed to accommodate the inner chamber, and an outer door that may be moved to open and close the outer housing; and an air supply module having a processing gas line, which supplies processing gas for processing the substrate into the inner chamber at a first pressure higher than atmospheric pressure, and a protective gas line, which supplies a protective gas to a protective space between the outer chamber and the inner chamber at a second pressure set in relation to the first pressure. The processing gas line comprises: an introduction section having a discharge port disposed in the protective space; and a transfer section having a connection port which is connected to the discharge port in the locked position and moved apart from the discharge port in the open position, the transfer section being formed to transfer the processing gas, input from the introduction section, into the inner housing.

The present invention relates to a high-pressure substrate processing apparatus and a processing gas line used therefor.

### BACKGROUND ART

In general, various processing may be performed on a semiconductor wafer during a manufacturing process of a semiconductor device. Examples of the processing may include oxidation, nitriding, deposition, silicide, ion implantation, and the like. The example may also include a hydrogen or deuterium heat treatment process for improving interface characteristics of the semiconductor device.

A gas used for the processing may be supplied into a chamber to reach a high pressure and act on a semiconductor substrate. For gas supply, a hose connected to a gas supply facility of a factory may extend into the chamber. As a chamber door is elevated, a portion of the hose may also be required to be elevated. To enable this feature, the hose may be made of a material that is easily bendable.

As the hose is repeatedly bent, the hose may become structurally weak. Gas leakage may occur at a weakened portion of the hose.

The related art described above is technical information that the inventor possessed to derive embodiments of the present invention or acquired during its derivation process, and may not necessarily be considered to belong to the known art publicly disclosed prior to this application.

### DISCLOSURE

### Technical Problem

An object of the present invention is to provide a high-pressure substrate processing apparatus structurally eliminating a risk of gas leakage caused by bending of a line for supplying a processing gas into a chamber, and a processing gas line used therefor.

### Technical Solution

According to an embodiment of the present invention, provided is a high-pressure substrate processing apparatus including: an inner chamber including an inner housing configured to accommodate a substrate to be processed, and an inner door configured to be movable between a locked position for enclosing the inner housing and an open position for opening the inner housing; an outer chamber including an outer housing accommodating the inner chamber, and an outer door configured to be movable to open and close the outer housing; and a gas supply module including a processing gas line configured to supply a processing gas for processing the substrate into the inner chamber to reach a first pressure higher than atmospheric pressure, and a protective gas line configured to supply a protective gas to a protective space between the outer chamber and the inner chamber to reach a second pressure set in relation to the first pressure, wherein the processing gas line includes an introduction section including a discharge port disposed in the protective space, and a transfer section including a connection port connected to the discharge port when the inner door is in the locked position and configured to be movable to be spaced apart from the discharge port when the inner door is in the open position and to transfer the processing gas received from the introduction section into the inner housing.

The introduction section may pass through the outer housing.

The introduction section may be fixed to the outer housing.

The outer housing may include a support member configured to support the discharge port against a force received from the connection port as the inner door is moved from the open position to the locked position.

The transfer section may be installed at the inner door and configured to be movable along with the inner door when the inner door is moved between the locked position and the open position.

The transfer section may include a fixed part installed on the inner door, and a moving part positioned to correspond to the discharge port and configured to be movable relative to the fixed part.

The moving part may be configured to be movable along a movement direction between the locked position and the open position.

The transfer section may further include a first shock-absorbing member installed on one of the fixed part and the moving part and configured to alleviate an impact caused by collision with the other one of the fixed part and the moving part.

The inner chamber may further include a second shock-absorbing member installed on at least one of the inner door and the inner housing and configured to alleviate an impact caused by collision with the other one of the inner door and the inner housing, and the first shock-absorbing member and the second shock-absorbing member may be made of the same material and have the same thickness.

The second pressure may be higher than the first pressure.

According to another embodiment of the present invention, provided is a processing gas line used for a high-pressure substrate processing apparatus, the line including: an introduction section including a discharge port disposed in an outer housing of the high-pressure substrate processing apparatus; and a transfer section including a connection port, which is connected to the discharge port in a locked position in which an inner door of the high-pressure substrate processing apparatus closes an inner housing accommodated in the outer housing and configured to be movable to be spaced apart from the discharge port in an open position in which the inner door opens the inner housing and to transfer a processing gas received from the introduction section into the inner housing, wherein the transfer section includes a fixed part installed at the inner door, and a moving part positioned to correspond to the discharge port and configured to be movable relative to the fixed part.

The introduction section may pass through and be fixed to the outer housing.

The transfer section may further include a first shock-absorbing member installed on one of the fixed part and the moving part and configured to alleviate an impact caused by collision with the other one of the fixed part and the moving part.

In the line, in which the high-pressure substrate processing apparatus further includes a second shock-absorbing member installed on at least one of the inner door and the inner housing and configured to alleviate an impact caused by collision with the other one of the inner door and the inner housing, the first shock-absorbing member may have the same material and thickness as the second shock-absorbing member.

### Advantageous Effects

According to the high-pressure substrate processing apparatus of the present invention and the processing gas line used therefor, configured as described above, the processing gas line of the gas supply module, which supplies the processing gas into the inner chamber, may have the introduction section including the discharge port disposed in the protective space of the outer chamber, and the transfer section including the connection port connected to or spaced apart from the discharge port while moving based on the movement of the door of the inner chamber, thereby enabling the processing gas input from the introduction section to be transferred into the inner chamber through the transfer section while the discharge port and the connection port are connected to each other, and eliminating any need for the processing gas line to include a portion required to be bent. As a result, the risk of the processing gas leakage caused by the bending of the processing gas line may be structurally eliminated.

### DESCRIPTION OF DRAWINGS

FIG. 1 is a conceptual diagram of a high-pressure substrate processing apparatus 100 according to an embodiment of the present invention.

FIG. 2 is a conceptual diagram showing a locked position of the high-pressure substrate processing apparatus 100 in FIG. 1.

FIG. 3 is a conceptual diagram showing an open position of the high-pressure substrate processing apparatus 100 in FIG. 1.

FIG. 4 is a conceptual diagram showing a detailed structure of a processing gas line 200 in the locked position in FIG. 2.

FIG. 5 is a conceptual diagram showing a detailed structure of the processing gas line 200 in the open position in FIG. 3.

FIG. 6 is a conceptual diagram of an elevating drive module 150 for elevating an outer door 125 of an outer chamber 120.

### DETAILED DESCRIPTION

Hereinafter, a high-pressure substrate processing apparatus and a processing gas line used therefor according to embodiments of the present invention are described in detail with reference to the accompanying drawings. Throughout this specification, components that are the same as or similar to each other are denoted by reference numerals that are the same as or similar to each other even in a different embodiment, and a description thereof is replaced by the first description.

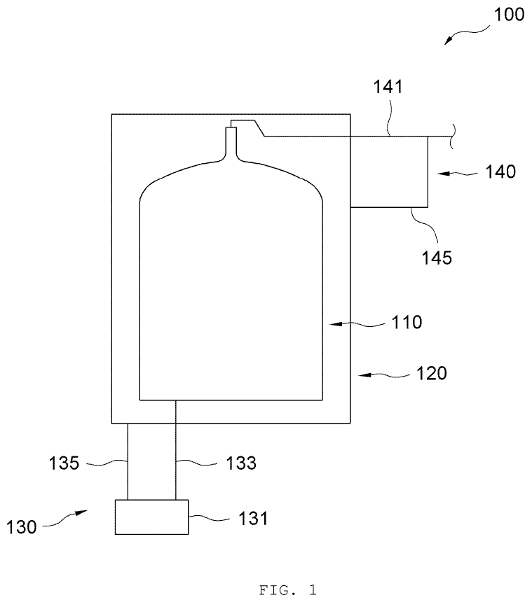

FIG. 1 is a conceptual diagram of a high-pressure substrate processing apparatus 100 according to an embodiment of the present invention.

Referring to FIG. 1, the high-pressure substrate processing apparatus 100 may include an inner chamber 110, an outer chamber 120, a gas supply module 130, and a gas exhaust module 140.

The inner chamber 110 may form an accommodating space that accommodates a substrate to be processed. The inner chamber 110 may be made of a non-metallic material, such as quartz, to reduce a risk of contamination of the substrate in a high-temperature and high-pressure working environment. A temperature in the inner chamber 110 may reach several hundred to several thousand degrees Celsius depending on an operation of a heater (not shown) disposed outside the inner chamber 110. The substrate may be, for example, a semiconductor wafer mounted on a holder. The substrate is not limited to the aforementioned wafer, and may be any other structure as long as the substrate serves as a base structure for manufacturing a circuit. For example, the substrate may also include glass for manufacturing a display. The holder may be a boat capable of stacking the substrates in a plurality of layers.

The outer chamber 120 may accommodate the inner chamber 110. Unlike the inner chamber 110, the outer chamber 120 may be made of a metal, as the outer chamber 120 is free from the risk of contamination of the substrate. The outer chamber 120 may have a hollow shape having an internal space that accommodates the inner chamber 110.

The gas supply module 130 is a component that supplies a gas to the inner chamber 110 and the outer chamber 120. The gas supply module 130 may have a gas supply device 131 that serves as a source of the gas. The gas supply device 131 may selectively supply, for example, hydrogen/deuterium gas, fluorine gas, ammonia gas, chlorine gas, or nitrogen gas, as a processing gas to the inner chamber 110. The gas supply device 131 may provide, for example, the nitrogen gas, which is an inert gas, as a protective gas to the outer chamber 120. The processing gas and the protective gas may be injected into the inner chamber 110 and the outer chamber 120 through a processing gas line 133 and a protective gas line 135, respectively. The protective gas injected into the outer chamber 120 may be specifically supplied to a space (i.e., protective space) between the outer chamber 120 and the inner chamber 110. The processing gas and the protective gas may be simply referred to as a process gas.

The process gas may be supplied to reach a pressure higher than atmospheric pressure, for example, to form a high pressure ranging from several atmospheres to several tens of atmospheres. When a pressure of the processing gas is referred to as a first pressure and a pressure of the protective gas is referred to as a second pressure, the first pressure and the second pressure may be maintained in a set relationship (or within a set range). For example, the second pressure may be set to be substantially equal to or slightly higher than the first pressure. Such a pressure relationship may prevent a processing gas from leaking from the inner chamber 110 and prevent the inner chamber 110 from breaking. The second pressure may be set to be slightly lower than the first pressure, which may also achieve a similar effect.

The gas exhaust module 140 is a component that exhausts the process gas. A gas exhaust pipe 141 may be connected to the top of the inner chamber 110 to exhaust the processing gas from the inner chamber 110. Similarly, a gas exhaust pipe 145 communicating with the outer chamber 120 may be provided to exhaust the protective gas from the outer chamber 120. The gas exhaust pipes 141 and 145 may be connected to each other, and the processing gas may thus be diluted with the protective gas during an exhaust process, thereby lowering its concentration.

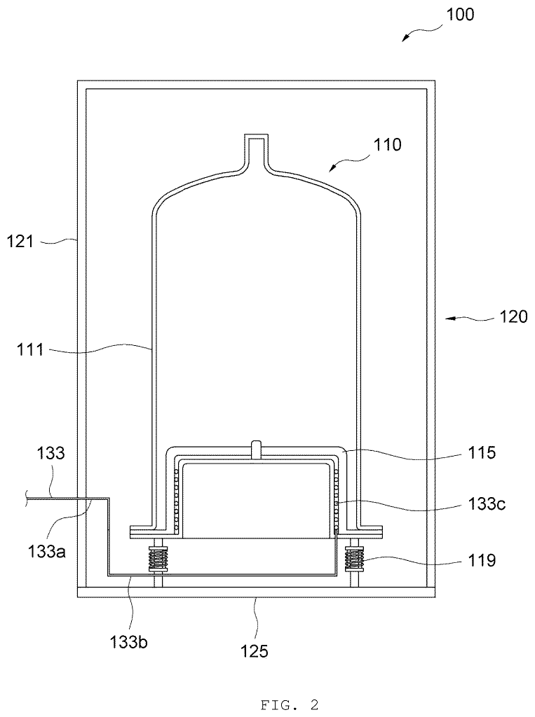

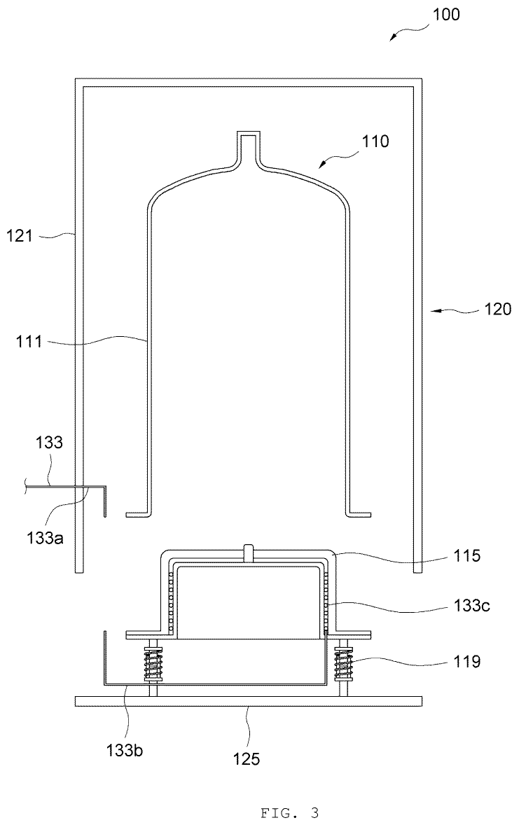

A specific configuration of the processing gas line 133 is described with reference to FIGS. 2 and 3. FIG. 2 is a conceptual diagram showing a locked position of the high-pressure substrate processing apparatus 100 in FIG. 1; and FIG. 3 is a conceptual diagram showing an open position of the high-pressure substrate processing apparatus 100 in FIG. 1. FIGS. 2 and 3 omit some components, such as the gas exhaust module 140 in FIG. 1.

Referring to FIGS. 2 and 3, the inner chamber 110 may include an inner housing 111 and an inner door 115. The inner housing 111 may form the accommodating space that accommodates the substrate, and its bottom may be open. The inner door 115 may close the open bottom of the inner housing 111. The inner door 115 may have an overall downward open trough shape, and the heater (not shown) may be installed in its open space. As the inner door 115 is moved, specifically lowered, the accommodating space may be opened (in the open position, see FIG. 3). As the inner door 115 is moved in an opposite direction, specifically raised, the accommodating space may be closed (in the locked position, see FIG. 2). The substrate may be loaded into or unloaded from the accommodating space in the open position.

The outer chamber 120 may also include an outer housing 121 and the outer door 125. The outer housing 121 may accommodate the entire inner chamber 110. Accordingly, the outer housing 121 may surround not only the inner housing 111 but also the inner door 115. The outer door 125 may also be moved to open and lock the outer housing 121. The outer door 125 may be connected to the inner door 115 via a support member 119 and may support the inner door 115. In that case, the inner door 115 may open and lock the inner housing 111 while being moved in conjunction with an elevating movement of the outer door 125. Expressions such as an ‘open state’ and a ‘locked state’ may also be applied as they are to a relationship between the outer housing 121 and the outer door 125.

The processing gas line 133 may include an introduction section 133a, a transfer section 133b, and a heating section 133c. The introduction section 133a may extend from the outside of the outer housing 121 into the outer housing 121. The transfer section 133b may be positioned inside the outer housing 121. The heating section 133c may be installed on the inner door 115. The heating section 133c differs from the transfer section 133b in that the heating section 133c is a section in which the processing gas is heated by the heater installed on the inner door 115. The heating section 133c may be helically wound around the inner door 115 to ensure sufficient heating time for the processing gas. Despite the aforementioned difference, the heating section 133c may be understood as a portion of the transfer section 133b in that the heating section 133c transfers the processing gas received from the introduction section 133a into the inner housing 111.

The transfer section 133b and the heating section 133c may be lowered along with the inner door 115 as the inner door 115 (and the outer door 125) is moved from the locked position to the open position. The introduction section 133a may remain fixed unlike the other sections 133b and 133c.

In the locked position, the introduction section 133a and the transfer section 133b may be connected to each other, and the processing gas may be supplied into the inner housing 111 by sequentially flowing through the introduction section 133a, the transfer section 133b, and the heating section 133c. In the open position, the supply of the processing gas into the inner chamber 110 may be stopped, and the transfer section 133b may be positioned to be spaced apart from the introduction section 133a.

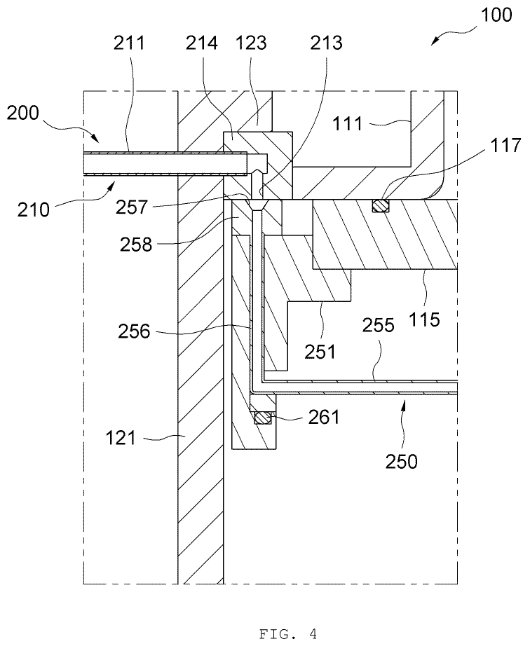

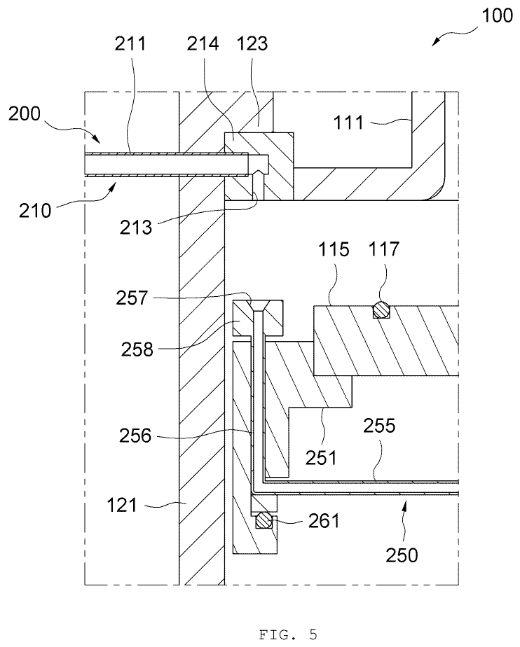

FIG. 4 is a conceptual diagram showing a detailed structure of a processing gas line 200 in the locked position in FIG. 2; and FIG. 5 is a conceptual diagram showing a detailed structure of the processing gas line 200 in the open position in FIG. 3. In FIGS. 4 and 5, for convenience of description, reference numeral 200 is assigned to the processing gas line 133.

Referring to FIGS. 4 and 5, the processing gas line 200 may include an introduction section 210 and a transfer section 250, as described above.

The introduction section 210 may include an introduction pipe 211 and a discharge port 213. The introduction pipe 211 may pass through the outer housing 121. The discharge port 213 may be disposed in the outer housing 121, specifically, in the protective space. As the discharge port 213 is positioned in the protective space, the discharge port 213 may be affected by (the pressure of) the protective gas. The discharge port 213 may be a hole of a discharge nozzle 214 coupled to the introduction pipe 211. Alternatively, the discharge port 213 may be an end hole of the introduction pipe 211 itself. The discharge port 213 may be disposed to face downward. A support member 123 may be disposed in the outer housing 121 to support the discharge nozzle 214 downward. The introduction section 210 may be entirely fixed to the outer housing 121 and unable to be moved by the elevation of the transfer section 250.

The transfer section 250 may include a fixed part 251, a moving part 255, and a first shock-absorbing member 261.

The fixed part 251 may be fixedly installed on the inner door 115. In contrast, the moving part 255 may be movable, specifically elevatable, relative to the fixed part 251. The moving part 255 may be positioned to correspond to the discharge port 213 of the fixed part 251.

The moving part 255 may include a moving pipe 256 and a connection port 257. The moving pipe 256 may be bent. For example, an upper portion of the moving pipe 256 may be arranged along an elevating direction, and a lower portion of the moving pipe 256 may be arranged along a direction intersecting the elevating direction. The connection port 257 may be an end hole of a connection nozzle 258 coupled to the upper portion of the moving pipe 256. Alternatively, the connection port 257 may be an end hole of the upper portion of the moving pipe 256 itself.

The first shock-absorbing member 261 is a component that alleviates an impact when the moving part 255 is lowered relative to the fixed part 251 and collides with the fixed part 251. The first shock-absorbing member 261 may be positioned below the fixed part 251. The first shock-absorbing member 261 may come into contact with the moving part 255 when the moving part 255 is lowered. The first shock-absorbing member 261 may be a member made of rubber, silicone, or the like. Alternatively, the first shock-absorbing member 261 may be installed on a portion of the moving part 255 that corresponds to the bottom of the fixed part 251.

The first shock-absorbing member 261 may have the same material and thickness as a second shock-absorbing member 117 installed on the inner door 115. The second shock-absorbing member 117 is a component that alleviates an impact caused by the inner door 115 colliding with the inner housing 111. The second shock-absorbing member 117 may also be installed in the inner housing 111.

Based on this configuration, as the inner door 115 is lowered, the transfer section 250 may also be lowered to be spaced apart from the introduction section 210. As the inner door 115 is raised, the transfer section 250 may also be raised, and the connection port 257 may thus be connected to the discharge port 213. During a connection process, a force received from the discharge port 213 and further received from the discharge nozzle 214 may be supported by the support member 123. In addition, a force received from the connection port 257 and further received from the connection nozzle 258 may be buffered by the first shock-absorbing member 261. A force received from the inner door 115 when the inner door 115 comes into contact with the inner housing 111 may be buffered by the second shock-absorbing member 117.

The first shock-absorbing member 261 and the second shock-absorbing member 117 may be made of the same material and have the same thickness, thereby adjusting coupling levels between the inner door 115 and the inner housing 111 and between the discharge port 213 and the connection port 257 to be identical to each other. This configuration may effectively prevent either of the two couplings from becoming incomplete.

The pressure of the protective gas (the second pressure) filling the protective space may serve to prevent the processing gas from leaking between the connection port 257 and the discharge port 213. Even if the processing gas leaks, the leaked processing gas may be safely exhausted (managed) by the gas exhaust module 140.

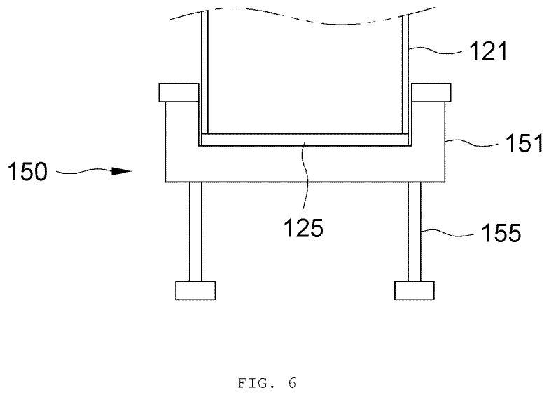

FIG. 6 is a conceptual diagram of the elevating drive module 150 for elevating the outer door 125 of the outer chamber 120.

Referring to FIG. 6, the elevating drive module 150 is provided to elevate the outer door 125 (and the inner door 115 connected thereto).

The elevating drive module 150 may include a support 151 and a guide frame 155.

The center of the support 151 may support the outer door 125. The center of the support 151 may be entirely arranged horizontally with respect to the ground.

The guide frame 155 may guide elevation of the support 151. The pair of guide frames 155 may be provided and coupled to both peripheries of the support 151. Accordingly, the pair of guide frames 155 may be symmetrically disposed with respect to the support 151.

Based on this configuration, the support 151 may be moved to be elevated or lowered by an actuator (e.g., ball screw, not shown). In that case, both the peripheries of the support 151 may be guided by the pair of guide frames 155. This configuration may allow the support 151, and further, the outer door 125 or the like, to be elevated in a stable position while maintaining a horizontal state.

The high-pressure substrate processing apparatus and the processing gas line used therefor as described above are not limited to the configurations and operation methods of the embodiments described above. The embodiments described above may be variously modified by selective combinations of all or some of the respective embodiments.

### INDUSTRIAL APPLICABILITY

The present invention has industrial applicability in a field of manufacturing a high-pressure substrate processing apparatus and a processing gas line used therefor.

1. A high-pressure substrate processing apparatus comprising:
an inner chamber including an inner housing configured to accommodate a substrate to be processed, and an inner door configured to be movable between a locked position for enclosing the inner housing and an open position for opening the inner housing;
an outer chamber including an outer housing accommodating the inner chamber, and an outer door configured to be movable to open and close the outer housing; and
a gas supply module including a processing gas line configured to supply a processing gas for processing the substrate into the inner chamber to reach a first pressure higher than atmospheric pressure, and a protective gas line configured to supply a protective gas to a protective space between the outer chamber and the inner chamber to reach a second pressure set in relation to the first pressure,
wherein the processing gas line includes
an introduction section including a discharge port disposed in the protective space, and
a transfer section including a connection port connected to the discharge port when the inner door is in the locked position and configured to be movable to be spaced apart from the discharge port when the inner door is in the open position and to transfer the processing gas received from the introduction section into the inner housing.

2. The apparatus of claim 1, wherein the introduction section passes through the outer housing.

3. The apparatus of claim 1, wherein the introduction section is fixed to the outer housing.

4. The apparatus of claim 1, wherein the outer housing includes a support member configured to support the discharge port against a force received from the connection port as the inner door is moved from the open position to the locked position.

5. The apparatus of claim 1, wherein the transfer section is installed at the inner door and configured to be movable along with the inner door when the inner door is moved between the locked position and the open position.

6. The apparatus of claim 1, wherein the transfer section includes
a fixed part installed on the inner door, and
a moving part positioned to correspond to the discharge port and configured to be movable relative to the fixed part.

7. The apparatus of claim 6, wherein the moving part is configured to be movable along a movement direction between the locked position and the open position.

8. The apparatus of claim 6, wherein the transfer section further includes a first shock-absorbing member installed on one of the fixed part and the moving part and configured to alleviate an impact caused by collision with the other one of the fixed part and the moving part.

9. The apparatus of claim 8, wherein the inner chamber further includes a second shock-absorbing member installed on at least one of the inner door and the inner housing and configured to alleviate an impact caused by collision with the other one of the inner door and the inner housing, and
the first shock-absorbing member and the second shock-absorbing member are made of the same material and have the same thickness.

10. The apparatus of claim 1, wherein the second pressure is higher than the first pressure.

11. A processing gas line used for a high-pressure substrate processing apparatus, the line comprising:
an introduction section including a discharge port disposed in an outer housing of the high-pressure substrate processing apparatus; and
a transfer section including a connection port, which is connected to the discharge port in a locked position in which an inner door of the high-pressure substrate processing apparatus encloses an inner housing accommodated in the outer housing and configured to be movable to be spaced apart from the discharge port in an open position in which the inner door opens the inner housing and to transfer a processing gas received from the introduction section into the inner housing,
wherein the transfer section includes
a fixed part installed at the inner door, and
a moving part positioned to correspond to the discharge port and configured to be movable relative to the fixed part.

12. The line of claim 11, wherein the introduction section passes through and is fixed to the outer housing.

13. The line of claim 11, wherein the transfer section further includes a first shock-absorbing member installed on one of the fixed part and the moving part and configured to alleviate an impact caused by collision with the other one of the fixed part and the moving part.

14. The line of claim 13, in which the high-pressure substrate processing apparatus further includes a second shock-absorbing member installed on at least one of the inner door and the inner housing and configured to alleviate an impact caused by collision with the other one of the inner door and the inner housing, wherein the first shock-absorbing member has the same material and thickness as the second shock-absorbing member.
